(19) United States
(12) Patent Application Publication
(10) Pub. No.: US 2012/0104465 A1
(43) Pub. Date: May 3, 2012

(54) IMAGE SENSOR

(76) Inventors: Jin-ho Kim, Seoul (KR); Chang-rok Moon, Seoul (KR)

(21) Appl. No.: 13/242,181

(22) Filed: Sep. 23, 2011

(30) Foreign Application Priority Data
Nov. 2, 2010 (KR) 10-2010-0108403

(51) Int. Cl. H01L 27/148

(52) U.S. Cl. 257/225; 257/E27.15

(57) ABSTRACT

An image sensor including: a substrate that includes a first surface onto which light is irradiated, a second surface opposite to the first surface, and a light receiving device disposed adjacent to the second surface; a transistor that includes a source region, a drain region, and a gate electrode disposed between the source region and the drain region, wherein the transistor is disposed on the second surface of the substrate; a wiring line that is disposed on the second surface of the substrate; and a plurality of contact plugs that are disposed on the source region, the drain region, or the gate electrode, wherein at least one of the plurality of contact plugs is connected to the wiring line.

### CROSS-REFERENCE TO RELATED APPLICATION

This application claims priority under 35 U.S.C. §119 to Korean Patent Application No. 10-2010-0108403, filed on Nov. 2, 2010, in the Korean Intellectual Property Office, the disclosure of which is incorporated by reference herein in its entirety.

### BACKGROUND

1. Technical Field

The inventive concept relates to an image sensor, and more particularly, to an image sensor including a plurality of contact plugs.

2. Discussion of the Related Art

An image sensor is a device that converts an optical image into an electrical signal. It is used in various devices such as digital cameras, camcorders, personal computer (PC) systems, game devices, security cameras, medical micro cameras, and robots. A backside illumination (or back-illuminated) image sensor is a type of digital image sensor that uses an arrangement of imaging elements to increase the amount of light captured and thereby improve low-light performance. The backside illumination image sensor converts an optical image to electric signals by forming a wiring layer on a front surface of a semiconductor layer and transmitting light incident on a back surface of the semiconductor layer, for example.

### SUMMARY

An exemplary embodiment of the inventive concept provides an image sensor that prevents a poor connection of a contact plug to inhibit defects from occurring in an image, and improves processing efficiency.

According to an exemplary embodiment of the inventive concept, there is provided an image sensor including: a substrate that includes a first surface onto which light is irradiated, a second surface opposite to the first surface, and a light receiving device disposed adjacent to the first surface; a transistor that includes a source region, a drain region, and a gate electrode disposed between the source region and the drain region, wherein the transistor is disposed on the second surface of the substrate; a first wiring line that is disposed on the second surface of the substrate; and a plurality of contact plugs that are disposed on the source region, the drain region, or the gate electrode, wherein the plurality of contact plugs is commonly connected to the first wiring line.

The plurality of contact plugs may electrically connect the source region, the drain region, or the gate electrode with the first wiring line.

The plurality of contact plugs may be arranged adjacent to each other in at least one direction.

The source region, the drain region, or the gate electrode may have a first length in a first direction and a second length greater than the first length in a second direction perpendicular to the first direction, and the plurality of contact plugs may be arranged adjacent to each other in the second direction.

The plurality of contact plugs may be arranged adjacent to each other in a direction in which the first wiring line extends.

The plurality of contact plugs may have different pitches.

The transistor may include at least one of a first transfer transistor, a reset transistor, a select transistor, or a driver transistor.

The light receiving device may be disposed at one side of the first transfer transistor, convert the light irradiated onto the first surface of the substrate into an electrical signal, and transfer the electrical signal to the first transfer transistor.

The image sensor may include a floating diffusion region, the light receiving device and at least another light receiving device, wherein at least the first transfer transistor and a second transfer transistor share the floating diffusion region.

The first transfer transistor and the second transfer transistor may be symmetrically disposed with respect to the floating diffusion region, the second transfer transistor may be disposed on the second surface of the substrate and comprises a source region, a drain region, and a gate electrode disposed between the source region and the drain region, first and second contact plugs may be connected to the gate electrode of the first transfer transistor and third and fourth contact plugs may be connected to the gate electrode of the second transfer transistor, wherein the first and third contact plugs may be disposed in a first column and spaced apart from each other at a first same interval, and the second and fourth contact plugs may be disposed in a second column and spaced apart from each other at a second interval.

The first transfer transistor and the second transfer transistor may be symmetrically disposed with respect to the floating diffusion region, the second transfer transistor may be disposed on the second surface of the substrate and includes a source region, a drain region, and a gate electrode disposed between the source region and drain region, and first and second contact plugs connected to the gate electrode of the first transfer transistor and third and fourth contact plugs connected to the gate electrode of the second transfer transistor may be symmetrically disposed with respect to the floating diffusion region.

A first contact plug may have the same area as that of a second contact plug.

A distance between first and second adjacent contact plugs may be less than a length of a side of one of the first and second contact plugs or a diameter of one of the first and second contact plugs.

The number of the plurality of contact plugs may be two.

The first wiring line may have a first width and a second width greater than the first width, wherein first wiring line may be connected to the contact plugs at the second width.

The image sensor may further include: a second wiring line disposed on the first wiring line; and a plurality of via plugs that are connected to the first wiring line and the second wiring line.

According to an exemplary embodiment of the inventive concept, an image sensor includes a switching device that includes a first terminal, a second terminal and a third terminal, wherein the third terminal is disposed between the first and second terminals; a first contact plug unit that includes a pair of first contact plugs, wherein the first contact plug unit is connected to the first, second or third terminals; and a first wiring line electrically connected to the first, second or third terminal via the first contact plug, wherein the switching device is disposed on a first side of a substrate opposite a second side of the substrate, and the second side receives light.

When the first contact plug is connected to the third terminal, the image sensor may further include: a second contact plug unit that includes a pair of second contact plugs, wherein the second contact plug unit is connected to the second terminal or the third terminal; a via plug connected to the first wiring line that is electrically connected to the third terminal via the first contact plug; and a second wiring line electrically connected to the first wiring line by the via plug.

According to an exemplary embodiment of the inventive concept, an image sensor includes a pixel including an active region, wherein the active region includes a photodiode region and a transistor region protruding away from the photodiode region, wherein the photodiode region includes a gate region of a first transistor, and the active region includes source, drain and gate regions of a second transistor; a pair of contact plugs connected to the gate region of the first transistor, or the gate, source or drain region of the second transistor; and a wiring line connected to the pair of contact plugs.

### BRIEF DESCRIPTION OF THE DRAWINGS

The above and other features of the inventive concept will become more apparent by describing in detail exemplary embodiments thereof with reference to the accompanying drawings in which:

FIG. 1 is a block diagram of an image sensor according to an exemplary embodiment of the inventive concept;

FIG. 2 is a circuit diagram of a unit pixel contained in the image sensor of FIG. 1, according to an exemplary embodiment of the inventive concept;

FIG. 3 shows layouts of the image sensor of FIG. 1, according to an exemplary embodiment of the inventive concept;

FIG. 4 is a circuit diagram of a unit pixel contained in the image sensor of FIG. 1, according to an exemplary embodiment of the inventive concept;

FIGS. 5A to 5C show layouts of an image sensor according to an exemplary embodiment of the inventive concept;

FIG. 6 shows layouts of an image sensor according to an exemplary embodiment of the inventive concept;

FIG. 7 shows layouts of an image sensor according to an exemplary embodiment of the inventive concept;

FIG. 8 is a cross-sectional view of an image sensor according to an exemplary embodiment of the inventive concept;

FIG. 9 is a cross-sectional view of an image sensor according to an exemplary embodiment of the inventive concept;

FIG. 10 is a cross-sectional view of an image sensor according to an exemplary embodiment of the inventive concept;

FIGS. 11A to 11E are cross-sectional views for describing a method of fabricating an image sensor according to an exemplary embodiment of the inventive concept; and

FIG. 12 is a block diagram of an electronic system including an image sensor according to an exemplary embodiment of the inventive concept.

### DETAILED DESCRIPTION OF THE EMBODIMENTS

Hereinafter, exemplary embodiments of the inventive concept will be described in detail with reference to the attached drawings. The inventive concept may, however, be embodied in many different forms and should not be construed as being limited to the exemplary embodiments set forth herein.

Image sensors may be classified as charge coupled device (CCD) image sensors and complementary metal oxide semiconductor (CMOS) image sensors. The CMOS image sensors are driven based on CMOS technology. CMOS image sensors may have various structures but generally include four transistors and one photodiode. When a photodiode of a CMOS image sensor receives light, the photodiode absorbs light energy and stores charges corresponding to the light intensity, and then, a transfer transistor of the CMOS image sensor transfers the charges stored in the photodiode to a floating diffusion region of the CMOS image sensor. When a select transistor of the CMOS image sensor is turned on, a driver transistor for a source follower of the CMOS image sensor outputs a voltage that varies in response to an electric potential of the floating diffusion region.

According to exemplary embodiments of the inventive concept, the image sensor includes four transistors. However, the image sensor may also include an image sensor including three transistors or an image sensor including five or more transistors, for example.

According to exemplary embodiments of the inventive concept, the image sensor uses a photodiode as a light receiving device. However, the image sensor may also include a photo transistor, a photo gate, a pinned photo diode (PPD) or any combination thereof as the light receiving device, for example.

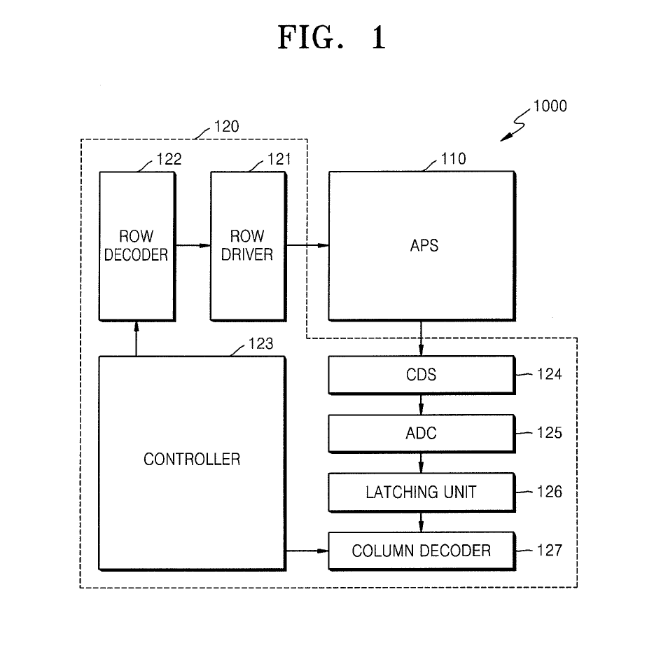

FIG. 1 is a block diagram of an image sensor 1000 according to an exemplary embodiment of the inventive concept.

Referring to FIG. 1, the image sensor 1000 includes an active pixel sensor (APS) array region 110 that includes pixels, wherein each pixel includes a photodiode (not shown), and a control circuit region 120 for operating the APS array region 110. The pixels may be two-dimensionally arranged in a matrix shape.

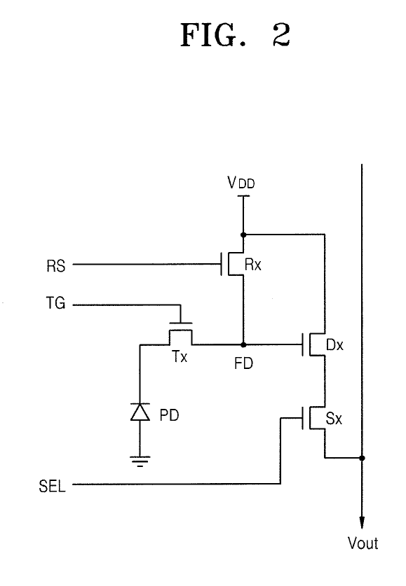

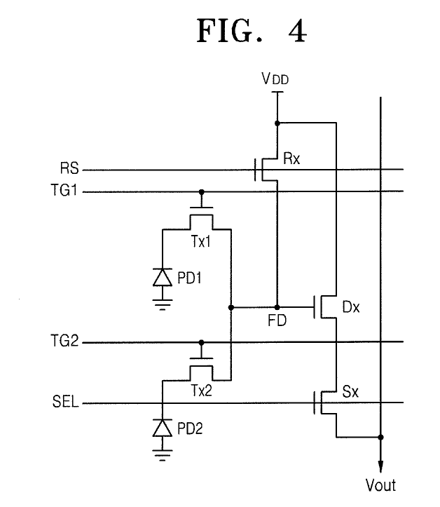

A unit pixel of the APS array region 110 may have a circuit configuration equivalent to that shown in FIGS. 2 and 4. The APS array region 110 converts an optical signal into an electrical signal and operates by receiving a plurality of operating signals such as a pixel selection signal SEL, a reset signal RS, and a transfer signal TG, TG1, or TG2 from a row driver 121 as shown in FIGS. 2 and 4. In addition, the electrical signal is provided to a correlated double sampler (CDS) 124 via a vertical signal line (an output line Vout of FIGS. 2 and 4).

The control circuit region 120 may include a controller 123, a row decoder 122, the row driver 121, the CDS 124, an analog-digital converter (ADC) 125, a latching unit 126 and a column decoder 127.

The controller 123 provides a control signal to the row decoder 122 and the column decoder 127. The row driver 121 provides a plurality of driving signals, for driving the pixels, to the APS array region 110 based on a result of a decoding performed in the row decoder 122. When the pixels are arranged in the matrix shape, a driving signal may be provided to each of the pixel rows.

The CDS 124 receives an electrical signal formed in the APS array region 110 via the vertical signal line (the output line Vout of FIGS. 2 and 4) and samples and holds the received electrical signal. In other words, both a noise level and a signal (e.g., voltage/current) level of the received electrical signal are measured so that the CDS 124 can output a difference between the noise level and the signal level as an analog signal.

The ADC 125 outputs a digital signal corresponding to the analog signal of the level difference output by the CDS 124.

The latching unit 126 latches the digital signal, and the latched signal is sequentially output to an image signal processing unit (not shown) based on a result of a decoding performed in the column decoder 127.

FIG. 2 is a circuit diagram of a unit pixel contained in the image sensor 1000 of FIG. 1, according to an exemplary embodiment of the inventive concept. More specifically, FIG. 2 shows an equivalent circuit diagram of a unit pixel including one photodiode and four transistors.

Referring to FIG. 2, the unit pixel may include a photodiode PD, a transfer transistor Tx, a reset transistor Rx, a driver transistor Dx, and a select transistor Sx.

The photodiode PD receives light and generates optical charges, and the transfer transistor Tx transmits the optical charges from the photodiode PD to a floating diffusion region FD.

In addition, the reset transistor Rx periodically resets the floating diffusion region FD. The driver transistor Dx functions as a source follower buffer amplifier and buffers a signal according to the charges of the floating diffusion region FD. The select transistor Sx functions as a switching and addressing device to select the unit pixel. In this regard, the reset signal RS is applied to a gate of the reset transistor Rx, and the transfer signal TG is applied to a gate of the transfer transistor Tx. In addition, the pixel selection SEL is applied to a gate of the select transistor Sx.

A source of the reset transistor Rx is connected to a power voltage source V_{DD}. When the reset transistor Rx is turned on by applying the reset signal RS to the gate of the reset transistor Rx, an electric potential of the floating diffusion region FD is charged by the power voltage V_{DD} from the source of the reset transistor Rx, and thus, the floating diffusion region FD is reset to a predetermined voltage (e.g., V_{DD}−Vₜₕ, where Vₜₕ is a threshold voltage of the reset transistor Rx).

The charges of the floating diffusion region FD are applied to the gate of the driver transistor Dx to control a current that flows in the select transistor Sx turned on by the pixel selection signal SEL applied to the gate of the select transistor Sx. The current flowing in the select transistor Sx is output as an output signal of the unit pixel via the output line Vout of the unit pixel and read out by a load transistor (not shown) connected to the output line Vout of the unit pixel.

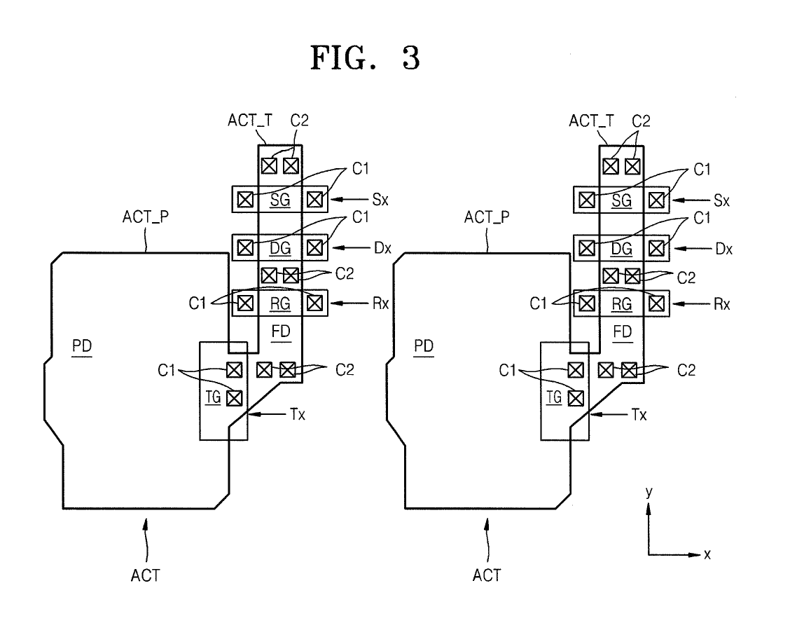

FIG. 3 shows layouts of an image sensor according to an exemplary embodiment of the inventive concept. More specifically, FIG. 3 shows two adjacent unit pixels, and each unit pixel has a configuration corresponding to the equivalent circuit diagram shown in FIG. 2.

Referring to FIG. 3, the unit pixels include active regions ACT defined in a pixel array region of a semiconductor substrate to have a predetermined shape. Each of the active regions ACT is divided into a photodiode region ACT_P having a photodiode PD and a transistor region ACT_T having transistors Sx, Dx, Rx, and Tx. In the active regions ACT, the photodiode region ACT_P, as a light receiving region, may have a predetermined shape, for example, a substantially square shape in a plan view, to occupy a predetermined area of the semiconductor substrate in the unit pixel. The transistor region ACT_T may partially contact the photodiode region ACT_P and have a linear shape with at least one bent portion at the point of contact.

A gate TG of the transfer transistor Tx is aligned near an interface between the photodiode region ACT_P and the transistor region ACT_T in the active region ACT. A gate RG of the reset transistor Rx, a gate DG of the driver transistor Dx, and a gate SG of the select transistor Sx are aligned in the transistor region ACT_T of the active region ACT to be spaced apart at intervals. The alignment of the transistors shown in FIG. 3 is an exemplary alignment and may vary without limitation.

A first contact plug C1 and a second contact plug C2 respectively refer to contact plugs formed in each of the gates RG, SG, DG, and TG and the active region ACT. According to the current exemplary embodiment, pairs of first contact plugs C1 may be formed on the gates RG, SG, DG, and TG and pairs of second contact plugs C2 may be formed on the active region ACT including the source and drain regions of the transistors Sx, Dx, Rx, and Tx. In other words, one pair of contact plugs may form one contact plug unit. The number of contact plugs forming one contact plug unit is not limited. For example, one contact plug unit may include more than two contact plugs.

The first contact plugs C1 that constitute one of the contact plug units may be arranged to be adjacent to each other in one direction, and the second contact plugs C2 that constitute one of the contact plug units may be arranged adjacent to each other in one direction. For example, the first contact plugs C1 may be disposed to be adjacent to each other in a direction in which a lower gate, on which the first contact plugs C1 are formed, extends. The first contact plugs C1 that form a contact plug unit may have the same size and same shape and may be formed using the same process, and the second contact plugs C2 that form a contact plug unit may have the same size and shape and may be formed using the same process.

According to the current exemplary embodiment, the image sensor may be driven when only one of the first contact plug C1 and only one of the second contact plug C2 of the contact plug units are electrically connected to an upper wiring (not shown). Accordingly, defects of the image sensor caused by poorly connected contact plugs may be reduced, and thus, a processing efficiency thereof may be improved. In addition, when a plurality of contact plugs in a contact plug unit are used for the electrical connection with the upper wiring, a resistive-capacitive (RC) delay caused by the resistance of the contact plugs may be reduced.

FIG. 4 is a circuit diagram of a unit pixel contained in the image sensor 1000 of FIG. 1, according to an exemplary embodiment of the inventive concept. More specifically, FIG. 4 shows an equivalent circuit diagram of a unit pixel including two photodiodes and five transistors.

Referring to FIG. 4, the unit pixel may be a 2-shared pixel including two photodiodes PD1 and PD2 which share a read-out device. In this regard, the read-out device is a device for reading out an optical signal of light incident on the photodiodes PD1 and PD2 and may include a reset transistor Rx, a driver transistor Dx, a select transistor Sx and two transfer transistors Tx1 and Tx2.

When the 2-shared pixel is used as the unit pixel, the area of the read-out device is reduced and the reduced area may be used to increase the size of the photodiodes PD1 and PD2. Accordingly, the light receiving efficiency of the unit pixel may be improved. In addition, sensitivity and signal saturation of the unit pixel may be improved.

As shown in FIG. 4, the reset signal RS is applied to a gate of the reset transistor Rx, the transfer signal TG1 is applied to a gate of the transfer transistor Tx1 and the transfer signal TG2 is applied to a gate of the transfer transistor Tx2. In addition, the pixel selection signal SEL is applied to a gate of the select transistor Sx.

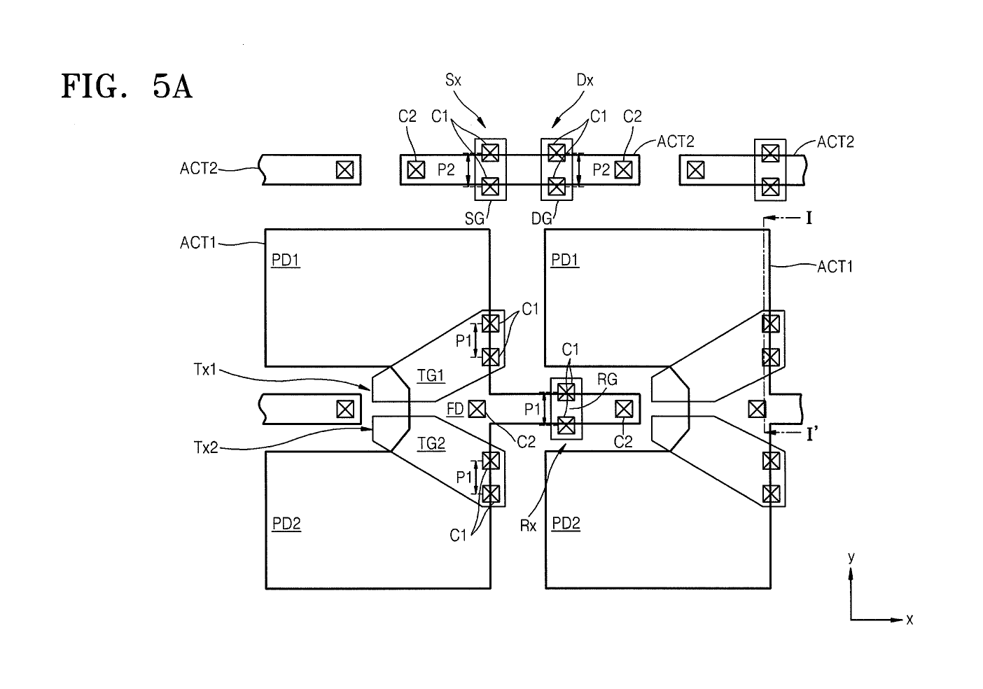

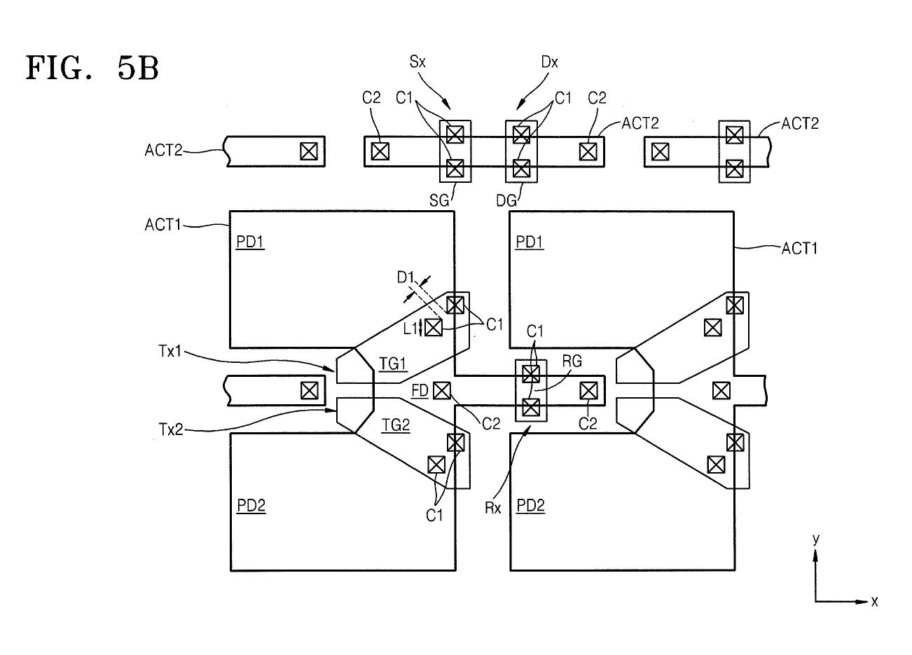

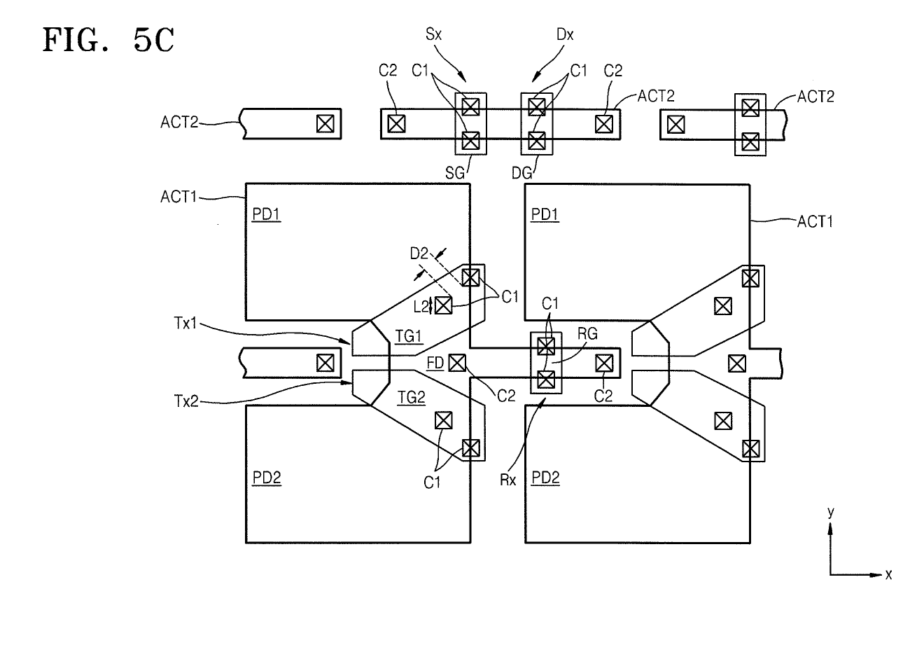

FIGS. 5A to 5C show layouts of an image sensor according to an exemplary embodiment of the inventive concept. More specifically, FIGS. 5A to 5C show two adjacent unit pixels, and each unit pixel has a configuration corresponding to the equivalent circuit diagram shown in FIG. 4.

Referring to FIG. 5A, the unit pixels include active regions ACT1 and ACT2 defined in a pixel array region of a semiconductor substrate to have a predetermined shape. First active regions ACT1, which include two photodiodes PD1 and PD2 sharing a floating diffusion region FD, are aligned in a matrix shape, and second active regions ACT2, which have an independent read-out device corresponding to each first active region ACT1, are aligned (e.g., arranged in a line). In other words, the first active region ACT1 and the second active region ACT2 may form a unit active region of the 2-shared pixel type. The first active region ACT1 and the second active region ACT2 may be aligned to be adjacent to each other in the y direction. However, as shown in FIG. 5A, the second active region ACT2 may be shifted in the x direction with respect to the first active region ACT1 by a predetermined distance.

The first active region ACT1 is a one axis merged dual lobe type active region. In other words, the dual lobe active region in which the photodiodes PD1 and PD2 are formed is connected to one axis active region via a connection active region in which the floating diffusion region FD is formed. The dual lobe active region faces the column direction with respect to the one axis active region, in other words, the dual lobe active region faces the y direction.

Gates RG, SG, and DG of the reset transistor Rx, the select transistor Sx, and the driver transistor Dx, which are three read-out devices, are separately formed in the first active region ACT1 and the second active region ACT2. The reset gate RG is formed in the one axis active region of the first active region ACT1, and the select gate SG and the driver gate DG may be formed in the second active region ACT2. The lateral alignment of the select gate SG and the driver gate DG may vary according to a wiring.

Two transfer gates TG1 and TG2 may be respectively formed between one of the lobe active regions and the connection active region of the first active region ACT1. The alignment of the transistors shown in FIG. 5A is an exemplary alignment and may vary without limitation.

A first contact plug C1 refers to contact plugs formed in each of the gates RG, SG, DG, TG1, and TG2 and a second contact plug C2 refers to contact plugs formed in each of the active regions ACT1 and ACT2. The active regions ACT1 and ACT2 may include source and drain regions of the transistors Rx, Sx, Dx, Tx1, and Tx2. According to the current exemplary embodiment, the first contact plug C1 formed on the gates RG, SG, DG, TG1, and TG2 may be a double contact plug in which two contact plugs form a pair. In other words, the two contact plugs may form one contact plug unit. The number of contact plugs forming the one contact plug unit is not limited, and one contact plug unit may include more than two contact plugs.

A pair of the first contact plugs C1 that form one contact plug unit may be arranged to be adjacent to each other in one direction. The direction may be the same as a direction in which lower gates, on which the first contact plugs C1 are formed, extend. For example, a pair of the first contact plugs C1 may be disposed to be adjacent to each other on the gate SG in the y direction which is a long axis direction of the gate SG.

The first contact plugs C1 may have the same size and same shape and may be formed using the same process. A pair of the first contact plugs C1 may have different pitches according to a gate pattern. For example, the first contact plugs C1 may have a first pitch P1 on the transfer gates TG1 and TG2 and the reset gate RG and have a second pitch P2 on the select gate SG and the driver gate DG. The first pitch P1 may be less than the second pitch P2. Alternatively, the first pitch P1 may be greater than or the same as the second pitch P2. In addition, the first and second pitches P1 and P2 may be selected according to the wiring fabrication process to be described later.

According to the current exemplary embodiment, by forming the contact plug unit including a pair of the first contact plugs C1 on the gate pattern, defects of the image sensor caused by poorly connected contact plugs may be reduced, and thus, a processing efficiency thereof may be improved. An RC delay caused by the resistance of the contact plugs may also be reduced.

Referring to FIG. 5B, the first contact plugs C1 of the transfer gates TG1 and TG2 are aligned in a different way from that of FIG. 5A. A pair of the first contact plugs C1 may be aligned to be adjacent to each other in one direction between the x direction and the y direction, e.g., in a diagonal direction. A pair of the first contact plugs C1 may be disposed in the diagonal direction according to a pattern of the transfer gates TG1 and TG2 in which the first contact plugs C1 are formed. A distance D1 between a pair of the first contact plugs C1 may be less than a length L1 of one first contact plug C1. In this regard, a line width of the wiring may be reduced in the wiring fabrication process to be described later. The length L1 may be a length of one side of the first contact plug C1 when the first contact plug C1, which is in contact with the gates RG, SG, DG, TG1, and TG2, is a square, or the length L1 may be a diameter when the first contact plug C1, which is in contact with the gates RG, SG, DG, TG1, and TG2, is a circle.

The two transfer gates TG1 and TG2 in the first active region ACT1 may be symmetrically formed with respect to the floating diffusion region FD in the column direction, e.g., in the y direction. In this case, the first contact plugs C1 formed on the first transfer gate TG1 and the second transfer gate TG2 may not be symmetrically formed with respect to the floating diffusion region FD in the y-direction, but may be formed to have the same shape. In other words, a pair of the first contact plugs C1 formed on the first transfer gate TG1 and a pair of the first contact plugs C1 formed in the second transfer gate TG2 may be disposed in the column direction, e.g., in the y direction to be spaced apart from each other at the same interval in the same column.

Referring to FIG. 5C, two photodiodes PD1 and PD2 sharing the floating diffusion region FD may be symmetrically formed with respect to the floating diffusion region FD in the column direction, e.g., in the y direction. In addition, the two transfer gates TG1 and TG2, and the first contact plugs C1 formed in the first transfer gate TG1 and the second transfer gate TG2 may be symmetrically aligned with respect to the floating diffusion region FD.

A distance D2 between a pair of the first contact plugs C1 may be greater than a length L2 of the first contact plug C1. The distance D2 may vary according to the line width of the wiring in the wiring fabrication process to be described later.

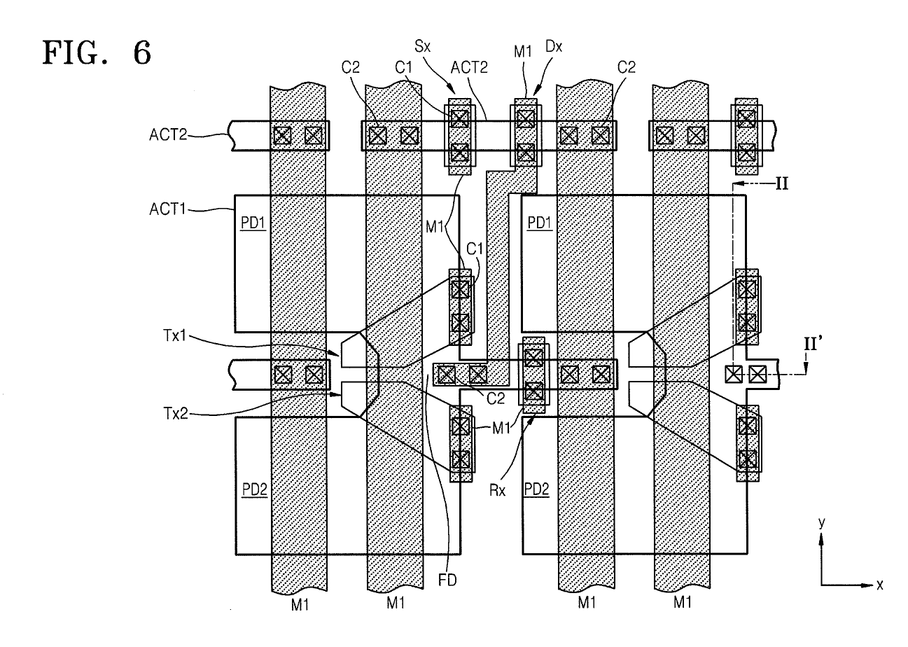

FIG. 6 shows layouts of an image sensor according to an exemplary embodiment of the inventive concept. More specifically, FIG. 6 shows two adjacent unit pixels, and each unit pixel has a configuration corresponding to the equivalent circuit diagram shown in FIG. 4.

In FIG. 6, like reference numerals denote like elements with respect to FIGS. 5A to 5C, and thus, those already described above may be omitted here. Referring to FIG. 6, first contact plugs C1 formed on the gates RG, SG, DG, TG1, and TG2 and second contact plugs C2 formed on the active regions ACT1 and ACT2 may be double contact plugs, e.g., the first contact plugs C1 and the second contact plugs C2 may each be a pair of contact plugs. Areas of the first and second contact plugs C1 and C2 which are in contact with the gates RG, SG, DG, TG1, and TG2 and the active regions ACT1 and ACT2 may be the same and the first and second contact plugs C1 and C2 may be formed using the same process.

A pair of the first contact plugs C1 may be arranged to be adjacent to each other in one direction. The direction may be the same as a direction in which lower gates, on which the first contact plugs C1 are formed, extend. The direction may also be the same as a direction in which an upper first wiring M1 extends.

A pair of the first contact plugs C2 may be arranged to be adjacent to each other in one direction. The direction may be the same as a direction in which the lower active regions ACT1 and ACT2, on which the second contact plugs C2 are formed, extend. For example, a pair of the second contact plugs C2 may be disposed to be adjacent to each other on the second active region ACT2 in the x direction that is a long axis direction of the second active region ACT2. A pair of the second contact plugs C2 may also be disposed to be adjacent to each other in a direction in which an upper first wiring M1 extends in the floating diffusion region FD.

The first wiring M1 may be formed on the first contact plugs C1 and the second contact plugs C2. The first wiring M1 may be connected to a second contact plug C2 disposed at the left side of the select transistor Sx to be connected to the output line Vout. A second contact plug C2 disposed at the right side of the driver transistor Dx may be connected to the power voltage source V_{DD} via the first wiring M1 with the source of the reset transistor Rx. The first wirings M1 may extend in one direction on the two photodiodes PD1 and PD2, e.g., in the y direction.

In addition, the first wiring M1 may be formed on the first contact plugs C1 of the gates of the driver transistor Dx, the select transistor Sx, the transfer transistors Tx1 and Tx2, and the reset transistor Rx, as landing pads. The landing pads may be formed to connect the first contact plugs C1 with another wiring (not shown).

In addition, the first wiring M1 may contact the first contact plug C1 on the gate of the driver transistor Dx with the second contact plug C2 of the floating diffusion region FD. Here, the first wiring M1 may be short to prevent a reduction in conversion efficiency caused by an increase in capacitance in a conductive layer forming the first wiring M1.

According to the current exemplary embodiment, the image sensor may be driven when only one of the first contact plug C1 and only one of the second contact plug C2 of the one contact plug units are electrically connected to the upper wiring M1 (not shown) by forming a contact plug unit including a pair of the second contact plugs C2 on the active regions ACT1 and ACT2 in addition to the plugs C1 formed on the gates RG, SG, DG, TG1, and TG2. Accordingly, defects of the image sensor caused by poorly connected contact plugs may be reduced, and thus, a processing efficiency thereof may be improved. An RC delay caused by the resistance of the contact plugs may also be reduced when a plurality of first and second contact plugs C1 and C2 of the contact plug units are electrically connected to the first wiring M1.

According to the current exemplary embodiment, in a backside illumination image sensor, light is irradiated from the backside of a substrate including the active regions ACT1 and ACT2, and thus, the light receiving efficiency of the photodiodes PD1 and PD2 is not affected when wiring is formed on the photodiodes PD1 and PD2. Accordingly, a wiring may be formed on the photodiodes PD1 and PD2 without impact to their light receiving efficiency. In addition, a width of the wiring formed on the photodiodes PD1 and PD2 including the first wiring M1 may be increased. Thus, although the contact plug unit includes a plurality of the first or second contact plugs C1 or C2, the contact plugs C1 or C2 may be stably connected to the wiring by controlling the width of the wiring.

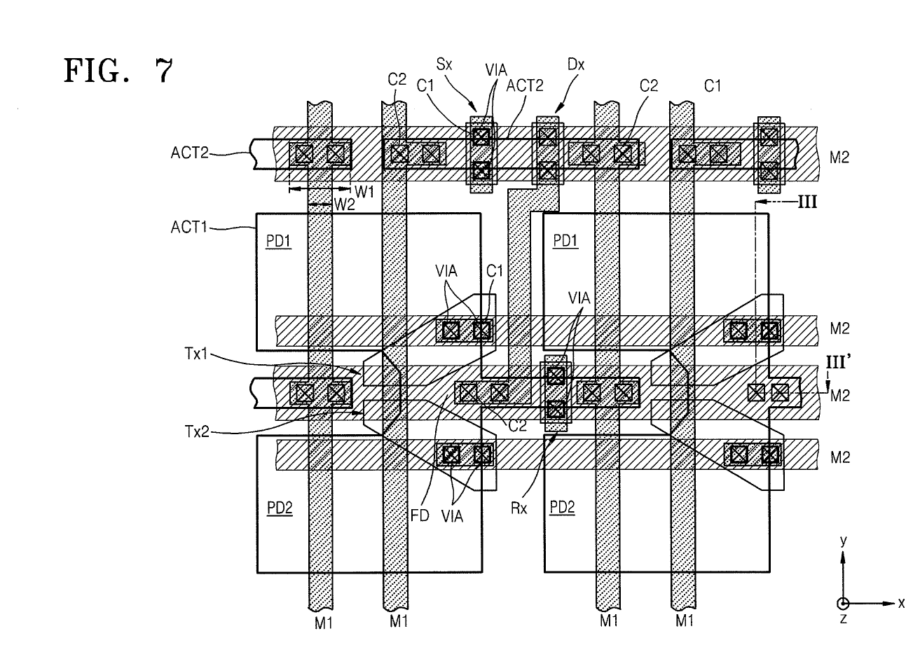

FIG. 7 shows layouts of an image sensor according to an exemplary embodiment of the inventive concept. More specifically, FIG. 7 shows two adjacent unit pixels, and each unit pixel has a configuration corresponding to the equivalent circuit diagram shown in FIG. 4.

In FIG. 7, like reference numerals denote like elements with respect to FIGS. 5A to 6, and those already described above may be omitted here. Referring to FIG. 7, the first wiring M1 may be formed on the first contact plugs C1 and the second contact plugs C2. The first contact plugs C1 formed on the gates of the transfer transistors Tx1 and Tx2 may be disposed to be adjacent to each other in the x direction, which are different from those shown in FIGS. 5A to 6.

The first wiring M1 may be connected to a second contact plug C2 disposed at the left side of the select transistor Sx to be connected to the output line Vout. The first wiring M1 may also be connected to a second contact plug C2 disposed at the right side of the driver transistor Dx and may be connected to the power voltage source V_{DD} with the source of the reset transistor Rx. The first wirings M1 may have a large width W1 in the connection region with the second contact plugs C2 to cover the second contact plugs C2 and a narrow width W2 in the region extending in the y direction, which are different from those shown in FIG. 6. The width W2 in the region extending in the y direction may be determined by the alignment of the first wiring M1 with other wiring.

In addition, the first wiring M1 may contact the first contact plug C1 of the driver gate DG with the second contact plug C2 of the floating diffusion region FD. In addition, the first wiring M1 may be formed on the first contact plugs C1 of the gates of the driver transistor Dx, the select transistor Sx, the transfer transistors Tx1 and Tx2, and the reset transistor Rx, as a landing pad.

Via plugs VIA may be formed on the first wiring M1. The via plugs VIA may be formed on the first wiring M1 on the gates of the select transistor Sx, the transfer transistors Tx1 and Tx2, and the reset transistor Rx. The via plug VIA may have an area that is the same as or larger than that of the first contact plug C1. In addition, the via plug VIA may be formed in the same position as the first contact plug C1 in the vertical direction (in the z direction of FIG. 7).

A second wiring M2 may be formed on the via plug VIA. The second wiring M2 may be connected to the gates of the select transistor Sx, the transfer transistors Tx1 and Tx2, and the reset transistor Rx via the via plug VIA, the first wiring M1, and the first contact plug C1. The second wiring M2 may extend in the x direction. Accordingly, the driving signal lines SEL, TG1, TG2, and RS (in FIG. 4) of the select transistor Sx, the transfer transistors Tx1 and Tx2, and the reset transistor Rx may be controlled such that unit pixels in the same row are simultaneously driven.

According to the current exemplary embodiment, in addition to the first contact plug C1 and the second contact plug C2, the via plugs VIA are provided. The via plugs VIA may be double via plugs to reduce defects in the connection of the via plugs VIA, and thus, a processing efficiency of an image sensor may be improved. An RC delay caused by the resistance of the via plugs VIA may also be reduced.

In addition, according to the current exemplary embodiment, in a backside illumination image sensor, when light is illuminated from the backside of a substrate, wiring may be aligned on the photodiodes PD1 and PD2 without impacting the light receiving efficiency thereof. Accordingly, by increasing the widths of the first wiring M1 and the second wiring M2, each pair of the first contact plugs C1 and the second contact plugs C2 and the via plugs VIA may be stably connected.

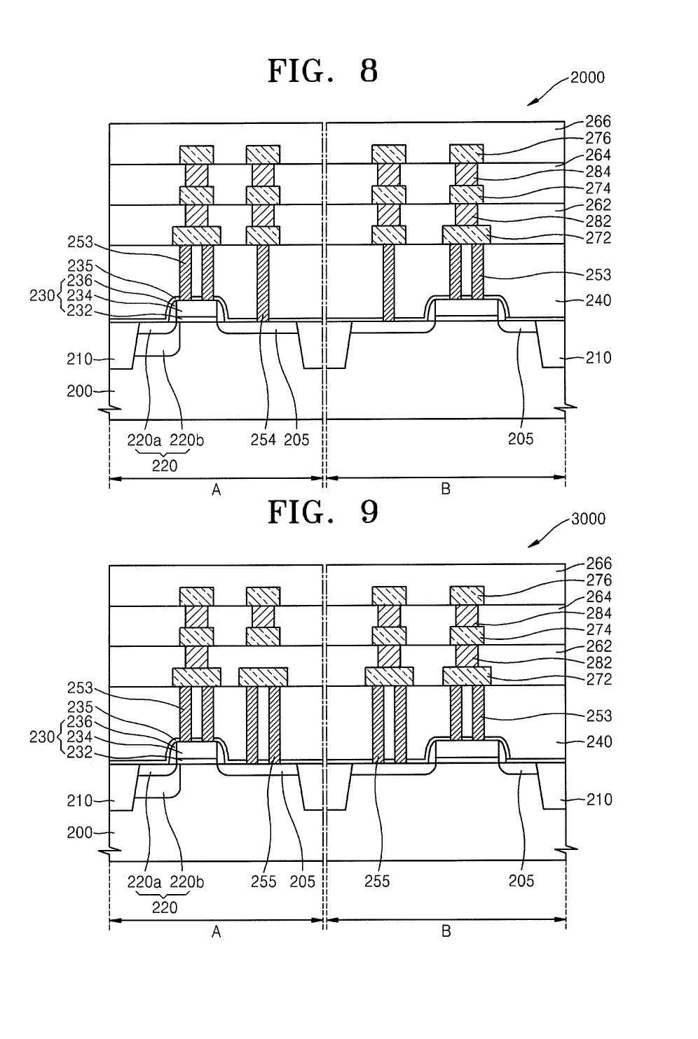

FIG. 8 is a cross-sectional view of an image sensor 2000 according to an exemplary embodiment of the inventive concept.

Referring to FIG. 8, the image sensor 2000 includes a substrate 200 including a pixel array region A and a peripheral circuit region B. The pixel array region A corresponds to a cross-section taken along line I-I′ of FIG. 5A.

The pixel array region A includes a region in which a photodiode 220 that is a light receiving unit is formed and regions in which transistors 230 such as a transfer transistor, a reset transistor, a driver transistor, and a select transistor are formed on a plurality of unit pixels aligned in the pixel array region A. The peripheral circuit region B is a region in which the transistors 230 for driving the transistors 230 contained in the pixel array region A are disposed.

The substrate 200 may be a semiconductor substrate. A device isolating layer 210 may be formed on the substrate 200 to define active regions ACT1 and ACT2 (in FIG. 5A).

The photodiode 220 is formed on the substrate 200. The photodiode 220 may include a first well 220a into which P-type impurities such as boron (B), gallium (Ga) and indium (In) are injected and a second well 220b into which N-type impurities such as phosphorus (P), arsenic (As) and antimony (Sb) are injected. The photodiode 220 may be a PN junction diode.

The transistors 230 are aligned on the substrate 200. The transistors 230 may include a gate insulating layer 232, a gate electrode layer 234, and a spacer 236 of a side wall. Source/drain regions 205 doped with impurities are formed on the substrate 200 at both sides of each of the transistors 230.

An etch-stop layer 235 and a first interlayer insulating layer 240 which cover the photodiode 220 and the transistors 230 are formed on the pixel array region A and the peripheral circuit region B. In the first interlayer insulating layer 240, a first contact plug 253 is formed on the transistors 230 and a second contact plug 254 is formed on an active region ACT1 or ACT2 of the substrate 200.

A plurality of interlayer insulating layers 262 and 264 and a passivation layer 266 may be formed on the first interlayer insulating layer 240. Wiring layers 272, 274, and 276 and via plugs 282 and 284 may be repeatedly formed in the interlayer insulating layers 262 and 264 and the passivation layer 266 to form a wiring structure.

The first contact plug 253 formed on the transistors 230 may be a double contact plug including two contact plugs as a pair. A pair of the first contact plugs 253 may be arranged to be adjacent to each other in one direction. The first contact plugs 253 and the second contact plug 254 may have the same size and same shape and may be formed using the same process. The first wiring layer 272 on the first contact plug 253 may be larger than that on the second contact plug 254 for a stable connection with the first contact plug 253.

A pair of the first contact plugs 253 may be connected to the gate electrode layer 234 of the transistors 230 having the same electric potential. In other words, a pair of the first contact plugs 253 may be used to perform a function for operating the image sensor 2000 according to the current exemplary embodiment. For example, if the transistor 230 is the transfer transistor Tx1 (in FIG. 5A), the first contact plug 253 may transfer an electrical signal for turning on and off the transistor 230 to cause the transistor 230 to transfer optical charges from the photodiode 220 to the floating diffusion region FD (in FIG. 5A).

FIG. 9 is a cross-sectional view of an image sensor 3000 according to an exemplary embodiment of the inventive concept.

In FIG. 9, like reference numerals denote like elements with respect to FIG. 8, and those already described above may be omitted here. Referring to FIG. 9, the pixel array region A of the image sensor 3000 corresponds to a cross-section taken along line II-II′ of FIG. 6.

Second contact plugs 255 formed on the active region of the substrate 200 may be a double contact plug including two contact plugs as a pair. In other words, the two contact plugs may form one contact plug unit. A pair of the second contact plugs 255 may be arranged to be adjacent to each other in one direction. The first wiring layer 272 on the second contact plugs 255 may have a large area for a stable connection with the second contact plugs 255.

A pair of the second contact plugs 255 may be connected to active regions having the same electric potential. In other words, a pair of the second contact plugs 255 may be used to perform a function for operating the image sensor 3000 according to the current exemplary embodiment. For example, if the active region of the pixel array region A shown in FIG. 9 is a floating diffusion region FD (in FIG. 6), the second contact plug 255 may transfer an electrical signal for applying charges to the gate of the driver transistor Dx (in FIG. 6). In addition, the first wiring layer 272 formed on a pair of the second contact plugs 255 may only be connected to the first contact plug C1 formed on the gate of the driver transistor Dx and may not be electrically connected to the second wiring layer 274.

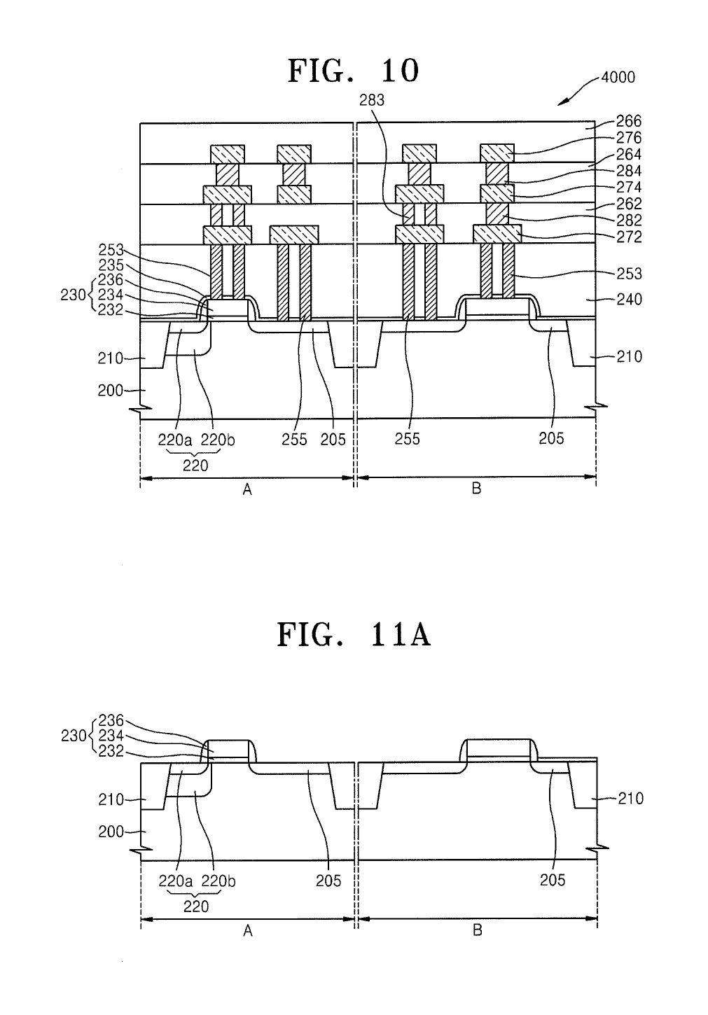

FIG. 10 is a cross-sectional view of an image sensor 4000 according to an exemplary embodiment of the inventive concept.

In FIG. 10, like reference numerals denote like elements with respect to FIGS. 8 and 9, and those already described above may be omitted here. Referring to FIG. 10, the pixel array region A of the image sensor 4000 corresponds to a cross-section taken along line III-III′ of FIG. 7.

Some of first via plugs 283 of first via plugs 282 formed on the first wiring layer 272 are a double via plug including two via plugs as a pair. In other words, the two via plugs may form one via plug unit. A pair of the first via plugs 283 may be arranged to be adjacent to each other in one direction. A pair of the first via plugs 283 may have a smaller size than that of the independently formed first via plugs 282. According to an exemplary embodiment, a pair of the first via plugs 283 may have the same size as that of the independently formed first via plugs 282. The first via plugs 282 and 283 may be formed in the same process. The second wiring layer 274 on the first via plugs 283 may have a large area for a stable connection with the first via plugs 283.

Although not shown in FIG. 10, the second via plugs 284 may be double via plugs. Additional wiring layers and via plugs may further be formed.

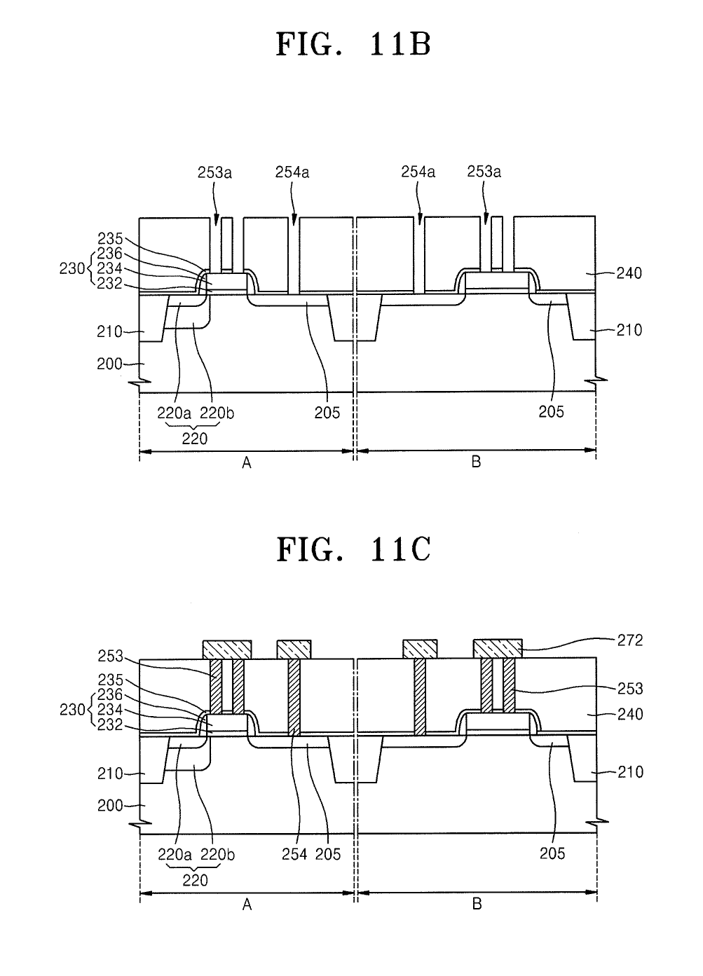

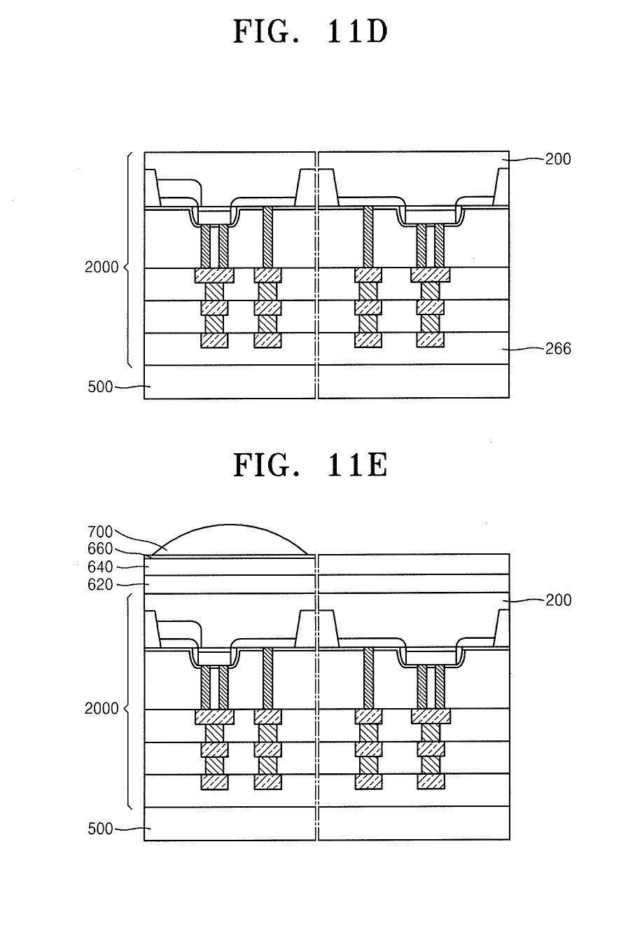

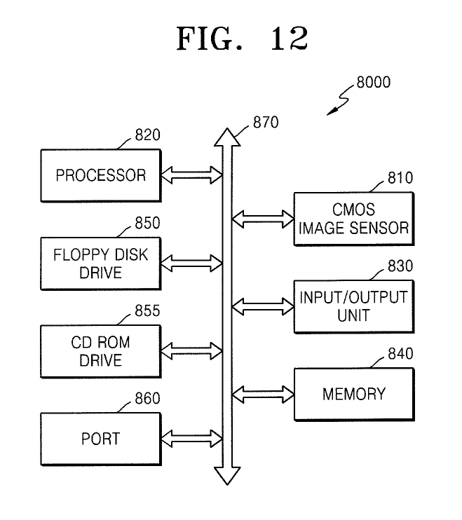

FIGS. 11A to 11E are cross-sectional views for describing a method of fabricating an image sensor according to an exemplary embodiment of the inventive concept.

Referring to FIG. 11A, a substrate 200 includes a pixel array region A and a peripheral circuit region B.

The substrate 200 may be a semiconductor substrate. For example, the semiconductor substrate may include silicon, silicon-on-insulator, silicon-on-sapphire, germanium, silicon-germanium, or gallium-arsenide. According to the current exemplary embodiment, the substrate 200 may be a P-type semiconductor substrate.

A device isolating layer 210 is formed on the substrate 200 to define active regions ACT1 and ACT2 (in FIG. 5A). The device isolating layer 210 may be formed by a shallow trench isolation (STI) process.

A photodiode 220 is formed on the substrate 200. The photodiode 220 may be a PN junction diode including a first well 220a into which P-type impurities are injected and a second well 220b into which N-type impurities are injected. However, the inventive concept is not limited thereto. According to an exemplary embodiment, the first well 220a may be formed by injecting N-type impurities, and the second well 220b may be formed by injecting P-type impurities. The injection of the impurities may be performed by a tilt ion implantation method. The order of forming the first well 220a and the second well 220a may be changed. According to an exemplary embodiment, the photodiode 220 is formed, and then, the transistors 230 are formed. According to an exemplary embodiment, the transistors 230 are formed, and then, the photodiode 220 is formed.

The transistors 230 are formed on the substrate 200. Although not shown in FIG. 11A, an epitaxial layer may be formed on the substrate 200, and the photodiode 220 and the transistors 230 may be formed on the epitaxial layer. The transistors 230 may be formed by sequentially stacking a gate insulating layer 232 and a gate electrode layer 234 and performing a patterning process thereon. A spacer 236 may be formed on both side walls of each of the transistors 230. Source/drain regions 205 doped with impurities are formed on the substrate 200 at both sides of each of the transistors 230. According to an exemplary embodiment, the transistor 230 formed in the pixel array region A and the transistor 230 formed in the peripheral circuit region B may be simultaneously formed using the same process.

The gate insulating layer 232 may include at least one selected from the group consisting of silicon oxide (SiO₂), silicon nitride (Si₃N₄), silicon oxynitride (SiON), hafnium oxide (HfO₂), hafnium silicon oxide (HfSiₓO_{y}), aluminum oxide (Al₂O₃), and zirconium oxide (ZrO₂). The gate electrode layer 232 may be a single layer or a complex layer structure including at least two of the above-described materials.

The gate electrode layer 234 may include at least one selected from the group consisting of polysilicon, aluminum (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), zirconium (Zr), a nitride thereof, and a silicide thereof. The gate electrode layer 234 may be a single layer or a complex layer structure including at least two of the above-described materials. Although not shown in FIG. 11A, the gate electrode layer 234 may further include a diffusion barrier (not shown). For example, the diffusion barrier may include tungsten nitride (WN), tantalum nitride (TaN) or titanium nitride (TiN).

The spacer 236 may include silicon nitride.

Referring to FIG. 11B, an etch-stop layer 235 is formed on the pixel array region A and the peripheral circuit region B to cover the photodiode 220 and the transistors 230. The etch-stop layer 235 may include silicon nitride (SiN).

A first interlayer insulating layer 240 is formed on the etch-stop layer 235. The first interlayer insulating layer 240 may be formed of an insulating material including silicon oxide (SiO₂). For example, the first interlayer insulating layer 240 may be a BoroPhosphoSilicate Glass (BPSG), Undoped Silica Glass (USG), Tetra Ethyle Ortho Silicate (TEOS) or High Density Plasma (HDP) layer.

A patterned mask layer (not shown) is formed on the first interlayer insulating layer 240, and the first interlayer insulating layer 240 is etched to form a first contact hole 253a on the transistors 230 and a second contact hole 254a on the active region of the substrate 200.

Referring to FIG. 11C, a conductive material is deposited on the first and second contact holes 253a and 254a to form the first contact plug 253 and the second contact plug 254. The conductive material may include tungsten (W). After the deposition process, a planarization process such as a chemical mechanical polishing (CMP) process or an etch-back process may be performed.

Then, a conductive material used to form the first wiring layer 272 is deposited on the first interlayer insulating layer 240 and the first and second contact plugs 253 and 254. The conductive material is patterned to form the first wiring layer 272. The first wiring layer 272 may include aluminum (Al) or copper (Cu).

Then, referring to FIG. 8, the second interlayer insulating layer 262 is formed on the first interlayer insulating layer 240 and the first wiring layer 272 and etched to form a first via hole (not shown). A conductive material is deposited on the first via hole (not shown) to form the first via plug 282. A conductive material is deposited on the first via plug 282 and patterned to form the second wiring layer 274. According to an exemplary embodiment, if the first via plug 282 and the second wiring layer 274 include copper (Cu), they may be formed by a dual damascene process.

In the same manner, the third interlayer insulating layer 264, the second via plug 284 and the third wiring layer 276 are formed. Finally, a passivation layer 266 is formed on the third interlayer insulating layer 264 and the third wiring layer 276 to form an image sensor 2000 according to the exemplary embodiment, as shown in FIG. 8.

According to the current exemplary embodiment, the image sensor 2000 has a wiring structure including the first to third wiring layers 272, 274, and 276, but the inventive concept is not limited thereto, and the number of the wiring layers may be greater or less than three. In addition, the number of the wiring layers formed in the pixel array region A may be different from the number of wiring layers formed in the peripheral circuit region B. Further, the wiring layers may be simultaneously formed on the pixel array region A and the peripheral circuit region B.

Referring to FIG. 11D, a supporting substrate 500 is bonded to the passivation layer 266 of the image sensor 2000. Then, the structure including the image sensor 2000 and the supporting substrate 500 is turned upside down, such that the image sensor 2000 becomes an upper layer and the supporting substrate 500 becomes a lower layer.

Then, the substrate 200 of the upper image sensor 2000 is partially removed using a grinder. By this process, the substrate 200 may have a thickness of several micrometers.

Referring to FIG. 11E, an anti-reflection layer 620 is formed on the inverted substrate 200. The anti-reflection layer 620 may protect the substrate 200 and prevent light scattering and light reflection. The anti-reflection layer 620 may have a multi-layered structure in which materials having different refractive indices are laminated. For example, the anti-reflection layer 620 may be a laminated layer in which an oxide layer and a nitride layer are laminated.

Then, a color filter 640 is formed on the anti-reflection layer 620, and a light transmitting layer 660 is formed on the color filter 640. The color filter 640 may be a color filter array including red (R), green (G) and blue (B). The light transmitting layer 660 may be a transparent resin layer, for example, a silicon oxide or silicon nitride layer. Then, a micro-lens 700 is formed on the light transmitting layer 660. Accordingly, incident light passes through the micro-lens 700, the color filter 640 selects desired colors, and the selected colors are stored in the photodiode 220 (in FIG. 8) via the anti-reflection layer 620.

Since the image sensor 2000 receives light from a backside of the substrate 200 which is opposite to the wiring layers, rather than from the surface having the wiring layers, the wiring layers may be formed without impacting the light receiving efficiency of the photodiode 220. Accordingly, a plurality of the first and second contact plugs 253 and 254 connected to the first to third wiring layers 272, 274 and 276 may be formed.

FIG. 12 is a block diagram of an electronic system 8000 including an image sensor, according to an exemplary embodiment of the inventive concept.

Referring to FIG. 12, the electronic system 8000 includes a CMOS image sensor 810 and processes an image output from the CMOS image sensor 810. For example, the electronic system 8000 may be any system including the CMOS image sensor 810 such as a computer system, a camera system, a scanner, or an image stabilizing system.

In particular, the electronic system 8000 may include a processor 820, an input/output unit 830, a memory 840, a floppy disk drive 850 and a compact disk read-only memory (CD ROM) drive 855, which communicate with one another via a bus 870. The CMOS image sensor 810 may include image sensors including contact plugs according to exemplary embodiments of the inventive concept as shown in FIGS. 1 to 11E.

The CMOS image sensor 810 may receive a control signal or data from the processor 820 and other devices of the electronic system 8000. The CMOS image sensor 810 provides a signal defining an image based on the received control signal or data to the processor 820, and the processor 820 may process the signal received from the image sensor 810.

The processor 820 may execute a program and control the electronic system 8000. The processor 820 may be a microprocessor, a digital signal processor, a micro-controller, or the like.

The input/output unit 830 may be used to input or output data of the electronic system 8000. The electronic system 8000 may be connected to an external device, e.g., a personal computer (PC) or a network, via the input/output unit 830 to exchange data with the external device. The input/output unit 830 may be a keypad, a keyboard, or a display.

The memory 840 may store codes and/or data for operating the processor 820 and/or may store data processed by the processor 820. A port 860, which is communicably coupled via the bus 870, may be connected to a video card, a sound card, a memory card, or a universal serial bus (USB) device or may exchange data with another system.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims.

What is claimed is:

1. An image sensor, comprising:
a substrate that comprises a first surface onto which light is irradiated, a second surface opposite to the first surface, and a light receiving device disposed adjacent to the second surface;
a transistor that comprises a source region, a drain region, and a gate electrode disposed between the source region and the drain region, wherein the transistor is disposed on the second surface of the substrate;
a first wiring line that is disposed on the second surface of the substrate; and
a plurality of contact plugs that are disposed on the source region, the drain region, or the gate electrode, wherein the plurality of contact plugs is commonly connected to the first wiring line.

2. The image sensor of claim 1, wherein the plurality of contact plugs electrically connects the source region, the drain region, or the gate electrode with the first wiring line.

3. The image sensor of claim 1, wherein the plurality of contact plugs are arranged adjacent to each other in at least one direction.

4. The image sensor of claim 3, wherein the source region, the drain region, or the gate electrode has a first length in a first direction and a second length greater than the first length in a second direction perpendicular to the first direction, and
the plurality of contact plugs are arranged adjacent to each other in the second direction.

5. The image sensor of claim 3, wherein the plurality of contact plugs are arranged adjacent to each other in a direction in which the first wiring line extends.

6. The image sensor of claim 1, wherein the plurality of contact plugs have different pitches.

7. The image sensor of claim 1, wherein the transistor comprises at least one of a first transfer transistor, a reset transistor, a select transistor, or a driver transistor.

8. The image sensor of claim 7, wherein the light receiving device is disposed at one side of the first transfer transistor, converts the light irradiated onto the first surface of the substrate into an electrical signal, and transfers the electrical signal to the first transfer transistor.

9. The image sensor of claim 7, wherein the image sensor comprises a floating diffusion region, the light receiving device and at least another light receiving device, wherein at least the first transfer transistor and a second transfer transistor share the floating diffusion region.

10. The image sensor of claim 9, wherein the first transfer transistor and the second transfer transistor are symmetrically disposed with respect to the floating diffusion region, the second transfer transistor is disposed on the second surface of the substrate and comprises a source region, a drain region, and a gate electrode disposed between the source region and the drain region, first and second contact plugs are connected to the gate electrode of the first transfer transistor and third and fourth contact plugs are connected to the gate electrode of the second transfer transistor, the first and third contact plugs are disposed in a first column and spaced apart from each other at a first interval, and the second and fourth contact plugs are disposed in a second column and spaced apart from each other at a second interval.

11. The image sensor of claim 9, wherein the first transfer transistor and the second transfer transistor are symmetrically disposed with respect to the floating diffusion region, the second transfer transistor is disposed on the second surface of the substrate and comprises a source region, a drain region, and a gate electrode disposed between the source region and the drain region, and
first and second contact plugs connected to the gate electrode of the first transfer transistor and third and fourth contact plugs connected to the gate electrode of the second transfer transistor are symmetrically disposed with respect to the floating diffusion region.

12. The image sensor of claim 1, wherein the number of the plurality of contact plugs is two.

13. The image sensor of claim 1, wherein the first wiring line has a first width and a second width greater than the first width, wherein the first wiring line is connected to the contact plugs at the second width.

14. The image sensor of claim 1, further comprising: a second wiring line disposed on the first wiring line; and
a plurality of via plugs that are connected to the first wiring line and the second wiring line.

15. The image sensor of claim 1, wherein a first contact plug has the same area as a second contact plug.

16. The image sensor of claim 1, wherein first and second contact plugs are adjacent to each other, and a distance between the first and second contact plugs is less than a length of a side of one of the first and second contact plugs or a diameter of one of the first and second contact plugs.

17. An image sensor, comprising:
a switching device that includes a first terminal, a second terminal and a third terminal, wherein the third terminal is disposed between the first and second terminals;
a first contact plug unit that includes a pair of first contact plugs, wherein the first contact plug unit is connected to the first, second or third terminals; and
a first wiring line electrically connected to the first, second or third terminal via the first contact plug,
wherein the switching device is disposed on a first side of a substrate opposite a second side of the substrate, and the second side receives light.

18. The image sensor of claim 17, wherein the first contact plug is connected to the third terminal, the image sensor further comprising:
a second contact plug unit that includes a pair of second contact plugs, wherein the second contact plug unit is connected to the second terminal or the third terminal;
a via plug connected to the first wiring line that is electrically connected to the third terminal via the first contact plug; and
a second wiring line electrically connected to the first wiring line by the via plugs.

19. An image sensor, comprising:
a pixel including an active region, wherein the active region includes a photodiode region and a transistor region protruding away from the photodiode region, wherein the photodiode region includes a gate region of a first transistor, and the active region includes source, drain and gate regions of a second transistor;
a pair of contact plugs connected to the gate region of the first transistor, or the gate, source or drain region of the second transistor; and
a wiring line connected to the pair of contact plugs.
